(19) United States
(12) Patent Application Publication
(10) Pub. No.: US 2024/0334838 A1
(43) Pub. Date: Oct. 3, 2024

(54) SOT-MRAM MEMORY CELL, MEMORY ARRAY, MEMORY, AND OPERATION METHOD

(71) Applicant: INSTITUTE OF MICROELECTRONICS, CHINESE ACADEMY OF SCIENCES, Beijing (CN)

(72) Inventors: Guozhong Xing, Beijing (CN); Long Liu, Beijing (CN); Xuefeng Zhao, Beijing (CN); Di Wang, Beijing (CN); Huai Lin, Beijing (CN); Hao Zhang, Beijing (CN); Ziwei Wang, Beijing (CN)

(21) Appl. No.: 18/293,846

(22) PCT Filed: Mar. 2, 2022
(86) PCT No.: PCT/CN2022/078760

§ 371 Date: Jan. 31, 2024

(51) Int. Cl. H10N 50/10; G11C 5/06; G11C 11/16; H10B 61/00; H10N 50/20; H10N 50/85; H10N 52/00

(52) U.S. Cl. CPC H10N 50/10; G11C 5/063; G11C 11/161; G11C 11/1673; G11C 11/1675; H10B 61/20; H10N 50/20; H10N 50/85; H10N 52/101

(57) ABSTRACT

The present disclosure provides an SOT-MRAM memory cell, including: a bottom electrode; a magnetic tunnel junction layer located on the bottom electrode; an orbital Hall effect layer located on the magnetic tunnel junction layer; a first transistor, a drain of which is connected to the orbital Hall effect layer; and a second transistor, a drain of which is connected to the bottom electrode. The present disclosure further provides an SOT-MRAM memory, an operation method, and an SOT-MRAM memory array.

### CROSS-REFERENCE TO RELATED APPLICATIONS

This application is a Section 371 National Stage Application of International Application No. PCT/CN2022/078760, filed on Mar. 2, 2022, entitled “SOT-MRAM MEMORY CELL, MEMORY ARRAY, MEMORY, AND OPERATION METHOD”, which published as WO 2023/164827 A1, on Sep. 7, 2023, not in English, the contents of which are hereby incorporated by reference in their entireties.

### TECHNICAL FIELD

The present disclosure relates to a field of magnetic random access memory technology, in particular to an SOT-MRAM memory cell, a memory array, a memory, and an operation method.

### BACKGROUND

SOT-MRAM (Spin-Orbit Torque Magnetic Random Access Memory), as a new generation of magnetic random access memory, has attracted widespread attention from academia and industry due to its characteristics such as sub-nanosecond writing speed, high data retention time, high durability, low power consumption, and radiation resistance, as well as its unique three-terminal device structure with read write separation, which overcomes bottlenecks of information writing speed and reliability of the previous generation STT-MRAM. SOT-MRAM is expected to become the next generation of universal non-volatile memory.

However, SOT-MRAM faces technical challenges that have not yet been fully overcome, namely, for SOT-MRAM with perpendicular magnetic anisotropy (PMA), data writing requires an assistance of an external in-plane magnetic field along a current direction, which limits the integration, miniaturization, and large-scale application of SOT-MRAM. The existing data writing methods without external magnetic field assistance, such as structural asymmetry, exchange bias/interlayer exchange coupling introducing built-in in-plane fields, have issues with difficulty in miniaturization and integration, as well as poor compatibility with CMOS processes. At the same time, SOT-MRAM in the prior art heavily uses expensive heavy metal materials as spin-orbit coupling layers, which is not conducive to further reducing the cost of SOT-MRAM.

### SUMMARY

In view of the above issues, the present disclosure provides an SOT-MRAM memory cell, a memory array, a memory, and an operation method, aiming to achieve an SOT-MRAM memory cell without external magnetic field assistance by combining the orbital Hall effect, the ferromagnetic material spin-orbit precession effect or the planar Hall effect, and the competition spin current.

As a first aspect of the present disclosure, an SOT-MRAM memory cell is provided, including: a bottom electrode: a magnetic tunnel junction layer located on the bottom electrode: an orbital Hall effect layer located on the magnetic tunnel junction layer: a first transistor, where a drain of the first transistor is connected to the orbital Hall effect layer; and a second transistor, where a drain of the second transistor is connected to the bottom electrode.

Furthermore, the memory cell further includes a heavy metal layer located between the magnetic tunnel junction layer and the orbital Hall effect layer.

Furthermore, the orbital Hall effect layer and the heavy metal layer are configured to conduct a write current. The orbital Hall effect layer is configured to convert the write current into an orbital-polarized orbital current through an orbital Hall effect. The heavy metal layer is configured to convert the write current into a spin-polarized spin current through a spin-orbit coupling.

Furthermore, the orbital current that diffuses into the heavy metal layer is converted into a spin current under a strong spin-orbit coupling effect of the heavy metal layer.

Furthermore, the spin current generated by the heavy metal layer has an opposite polarity to a polarity of the spin current converted from the orbital current, so as to form a competition spin current, where the competition spin current is configured to achieve a deterministic magnetization reversal without external magnetic field assistance.

Furthermore, the magnetic tunnel junction layer includes: a ferromagnetic reference layer, a non-magnetic barrier layer and a ferromagnetic free layer from bottom to top.

Furthermore, the ferromagnetic reference layer adopts a pinned structure, including: an antiferromagnetic structure layer, a second spatial layer and a reference layer from bottom to top.

Furthermore, the antiferromagnetic structure layer has an RKKY effect, including: a second ferromagnetic layer, a first spatial layer and a first ferromagnetic layer from bottom to top, and the first spatial layer is configured to form an antiferromagnetic coupling between the first ferromagnetic layer and the second ferromagnetic layer.

Furthermore, a structure composed of the first ferromagnetic layer and the second ferromagnetic layer is a synthetic ferromagnetic structure including periodically arranged Co/Pt or Co/Pd.

Furthermore, the memory cell further includes: a source line and a bit line. The source line is connected to the orbital Hall effect layer, and the bit line is connected to a source of the first transistor and a source of the second transistor, respectively.

Furthermore, the heavy metal layer is of one or more of Pt, Ta, W, or Gd.

Furthermore, the ferromagnetic reference layer is made of Co, CoFeB or Co/Pt, or includes a synthetic antiferromagnetic structure; the bottom electrode is made of one or more of Pt, Ta, or W: the non-magnetic barrier layer is made of MgO or Al₂O₃; the ferromagnetic free layer is made of Co, CoFe, or CoFeB; the orbital Hall effect layer is made of Cu or Cr.

As a second aspect of the present disclosure, an SOT-MRAM memory is provided, including the SOT-MRAM memory cell provided in the first aspect of the present disclosure.

As a third aspect of the present disclosure, an operation method of the SOT-MRAM memory is provided, including: controlling a voltage bias applied to a first transistor and a voltage bias applied to a second transistor in the SOT-MRAM memory, and performing a data writing operation and a data reading operation on the SOT-MRAM memory, respectively.

Furthermore, the performing a data reading operation on the SOT-MRAM memory includes: controlling the first transistor to be turned off and the second transistor to be turned on, so as to read data stored in the SOT-MRAM memory through a tunnel magnetoresistance effect.

Furthermore, the performing a data writing operation on the SOT-MRAM memory includes: controlling the first transistor to be turned on and the second transistor to be turned off, so as to form a competition spin current through an orbital Hall effect and a spin Hall effect to write data into the SOT-MRAM memory.

On a fourth aspect of the present disclosure, an SOT-MRAM memory array is provided, including a plurality of SOT-MRAM memory cells provided in the first aspect of the present disclosure, where the plurality of SOT-MRAM memory cells are arranged periodically.

As a fifth aspect of the present disclosure, an SOT-MRAM memory is provided, including the SOT-MRAM memory array provided in the fourth aspect of the present disclosure.

Embodiments of the present disclosure provide an SOT-MRAM memory cell, a memory array, and a memory. By configuring the orbital Hall effect layer to convert a write current into an orbital-polarized orbital current, and configuring the spin-orbit coupling layer to convert the write current and the orbital current diffusing into the spin-orbit coupling layer into spin currents with opposite spin polarizations to form a competition spin current, the memory cell achieves a full electrical controlled deterministic magnetization reversal without external magnetic field assistance. In addition, the structure of the SOT-MRAM device is simple, so that the use of expensive heavy metal materials may be reduced. The material system of the SOT-MRAM device is compatible with CMOS processes, which is conducive to the large-scale preparation and practicality of the SOT-MRAM device.

### BRIEF DESCRIPTION OF THE DRAWINGS

In order to have a more complete understanding of the present disclosure and its advantages, the following will be described in combination with the accompanying drawings, in which:

FIG. 1 schematically shows a diagram of an evolution of a research background of an SOT-MRAM in an embodiment of the present disclosure;

FIG. 2 schematically shows a diagram of a structure of an SOT-MRAM memory cell according to an embodiment of the present disclosure:

FIG. 3 schematically shows a diagram of a structure of a magnetic tunnel junction layer according to an embodiment of the present disclosure:

FIG. 4 schematically shows a diagram of achieving a deterministic magnetization reversal by the SOT-MRAM memory cell shown in FIG. 2 without external magnetic field assistance:

FIG. 5 schematically shows a diagram of a structure of an SOT-MRAM memory cell according to another embodiment of the present disclosure; and

FIG. 6 schematically shows a diagram of achieving a deterministic magnetization reversal by the SOT-MRAM memory cell shown in FIG. 5 without external magnetic field assistance.

### DETAILED DESCRIPTION OF EMBODIMENTS

Hereinafter, embodiments of the present disclosure will be described with reference to the accompanying drawings. However, it should be understood that these descriptions are merely illustrative and not intended to limit the scope of the present disclosure. In the following detailed description, for ease of explanation, many specific details are set forth to provide a comprehensive understanding of the embodiments of the present disclosure. However, it is evident that one or more embodiments may also be implemented without these specific details. Further, in the following, descriptions for known structures and technologies are omitted to avoid obscuring the concept of the present disclosure unnecessarily.

It should be understood that when an element (such as a layer, film, region, or substrate) is described as being “on” a further element, the element may be directly on the further element, or there may be an intermediate element therebetween. Moreover, in the specification and claims, when an element is described as “connected” to a further element, the element may be “directly connected” to the further element, or “connected” to the further element through a third element.

When elaborating on the embodiments of the present disclosure, for ease of explanation, a cross-sectional view representing a structure of a device may not be locally enlarged according to a general scale, and the diagram is only an example, which should not limit the scope of protection of the present disclosure. In addition, in actual production, three-dimensional spatial dimensions of length, width and depth should be included.

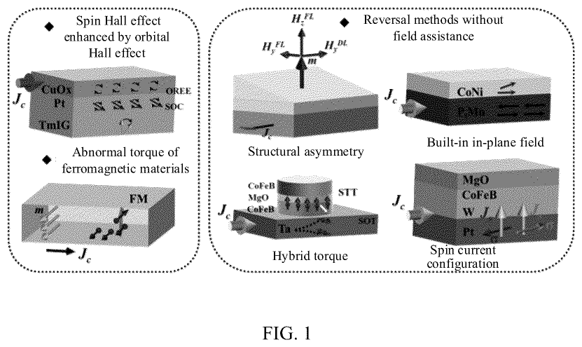

FIG. 1 schematically shows a diagram of an evolution of a research background of an SOT-MRAM in an embodiment of the present disclosure. The present disclosure mainly addresses issues such as the miniaturization of existing SOT-MRAMs magnetization reversal structures without external magnetic field assistance, the compatibility with CMOS, and the use of expensive heavy metal materials as spin-orbit coupling layers in existing SOT-MRAMs. There are mainly four types of existing mechanisms for magnetization reversal without external magnetic field assistance, namely a structural asymmetry type (such as a wedge-shaped barrier layer, a ferromagnetic layer, a heavy metal layer, etc.), a built-in bias field type (such as a ferromagnetic/antiferromagnetic exchange bias, an interlayer coupling, etc.), a hybrid type (such as magnetization reversal through a synergistic effect of STT and SOT working together, magnetization reversal based on a magnetic domain wall motion, etc.), and a spin current configuration (such as a gradient spin current, a competition spin current, a spin current with out-of-plane polarization, etc.).

Heavy metals are widely used as spin-orbit coupling layers in SOT-MRAMs due to spin-orbit coupling of heavy metals. However, heavy metals also suffer from high prices and high electrical resistivity. Since 2018, researchers have proposed the orbital Hall effect, and an orbital current may be converted into a spin current through spin-orbit coupling, enhancing a spin current conversion efficiency. In addition, in a light metal (such as Cu)/a ferromagnetic material, a combination of the orbital Hall effect and the spin-orbit coupling may achieve a spin current conversion efficiency equivalent to that of a heavy metal. The present disclosure aims to achieve an SOT-MRAM without external magnetic field assistance by combining the orbital Hall effect, a spin-orbit precession effect of ferromagnetic materials or the planar Hall effect, and the competition spin current.

For the problems existing in the prior art, the present disclosure provides an SOT-MRAM memory cell, including: a bottom electrode: a magnetic tunnel junction layer located on the bottom electrode: an orbital Hall effect layer located on the magnetic tunnel junction layer: a first transistor, where a drain of the first transistor is connected to the orbital Hall effect layer; and a second transistor, where a drain of the second transistor is connected to the bottom electrode.

According to the SOT-MRAM memory cell provided by the embodiments of the present disclosure, by configuring the orbital Hall effect layer to convert a write current into an orbital-polarized orbital current, and configuring the spin-orbit coupling layer to convert the write current and the orbital current diffusing into the spin-orbit coupling layer into spin currents with opposite spin polarizations to form a competition spin current, the SOT-MRAM memory cell achieves a full electrical controlled deterministic magnetization reversal without external magnetic field assistance. The structure of the SOT-MRAM device provided by the present disclosure is simple, so that the use of expensive heavy metal materials may be reduced. The material system of the SOT-MRAM device is compatible with CMOS processes, which is conducive to the large-scale preparation and practicality of the SOT-MRAM device.

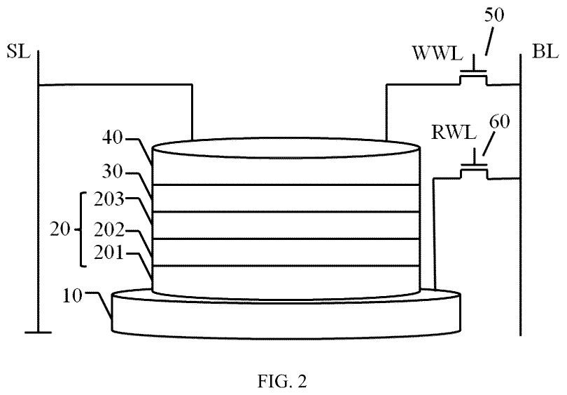

The following will provide a detailed explanation of the technical solution of the present disclosure in combination with a structure of the SOT-MRAM memory cell in specific embodiments of the present disclosure. It should be understood that material layers, shapes, and structures of each part in the structure of the SOT-MRAM memory cell shown in FIG. 2 to FIG. 5 are only exemplary to help those skilled in the art in understanding the technical solution of the present disclosure, and are not intended to limit the scope of protection of the present disclosure.

FIG. 2 schematically shows a diagram of a structure of an SOT-MRAM memory cell according to an embodiment of the present disclosure.

As shown in FIG. 2, an SOT-MRAM memory cell in an embodiment of the present disclosure includes: a bottom electrode 10, a magnetic tunnel junction layer 20, a heavy metal layer 30, an orbital Hall effect layer 40, a first transistor 50 and a second transistor 60 from bottom to top. A drain of the first transistor 50 is connected to a top portion of the orbital Hall effect layer 40, and a drain of the second transistor 60 is connected to a top portion of the bottom electrode 10. The magnetic tunnel junction layer 20 is of a spin-orbit torque magnetic tunnel junction (SOT-MTJ).

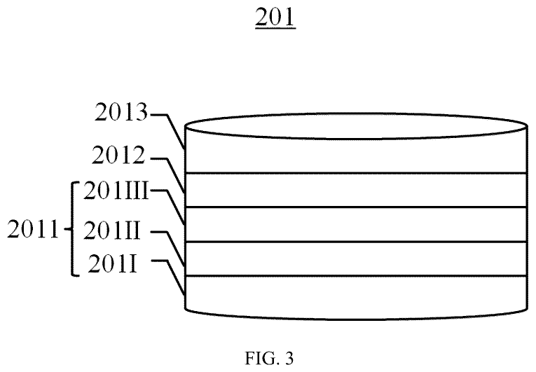

In an embodiment of the present disclosure, as shown in FIG. 2 and FIG. 3, the magnetic tunnel junction layer 20 includes a ferromagnetic reference layer 201, a non-magnetic barrier layer 202 and a ferromagnetic free layer 203 from bottom to top. The ferromagnetic reference layer 201 adopts a pinned structure and specifically includes: an antiferromagnetic structure layer 2011, a second spatial layer 2012 and a reference layer 2013 from bottom to top.

Specifically, as shown in FIG. 3, the antiferromagnetic structure layer 2011 has an RKKY (Ruderman-Kittel-Kasuya-Yosida) effect and specifically includes: a second ferromagnetic layer 201I, a first spatial layer 201II and a first ferromagnetic layer 201III from bottom to top. The first spatial layer 201II is used to form an antiferromagnetic coupling between the first ferromagnetic layer 201III and the second ferromagnetic layer 201I. The second ferromagnetic layer 201I, the first spatial layer 201II, and the first ferromagnetic layer 201III achieve a synthetic antiferromagnetic structure (SAF) through the RKKY effect.

Further, a structure composed of the first ferromagnetic layer 201III and the second ferromagnetic layer 201I is a synthetic ferromagnetic structure including periodically arranged Co/Pt or Co/Pd.

According to an embodiment of the present disclosure, the SOT-MRAM memory cell further includes: a source line SL and a bit line BL. The source line SL is connected to the orbital Hall effect layer 40. The bit line BL is connected to a source of the first transistor 50 and a source of the second transistor 60, respectively. A gate of the first transistor 50 and a gate of the second transistor 60 are used to receive a bias voltage for writing and a bias voltage for reading, respectively.

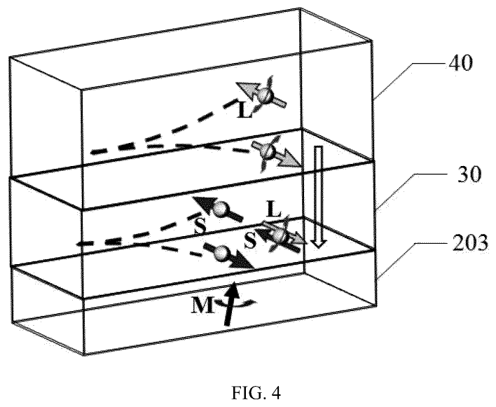

In this embodiment, the orbital Hall effect layer 40 and the heavy metal layer 30 are used to be conduct a write current. As shown in FIG. 4, the orbital Hall effect layer 40 is used to convert the write current into an orbital current with orbital magnetic torque (L) polarization through the orbital Hall effect, and such orbital current may diffuse into the heavy metal layer 30. The heavy metal layer 30 is used to convert the write current into a spin current with spin (S) polarization through spin-orbit coupling, while the orbital current that diffuses into the heavy metal layer 30 is converted into a spin current under the strong spin-orbit coupling effect of the heavy metal layer 30. A spin polarization direction of the spin current is determined by a polarity of the spin-orbit coupling of the heavy metal.

As shown in FIG. 4, at an interface between the heavy metal layer 30 and the ferromagnetic free layer 203, a polarization direction of the intrinsic spin current and a polarization direction of the spin current converted from the orbital current are opposite, so that the intrinsic spin current and the spin current converted from the orbital current form a competition spin current, thereby achieving deterministic magnetization reversal without external magnetic field assistance.

In an embodiment of the present disclosure, the heavy metal layer 30 is of one or more of Pt, Ta, W, or Gd. A layer thickness of the heavy metal layer 30 may be set according to actual application requirements, which will not be limited by embodiments of the present disclosure.

Specifically, the ferromagnetic reference layer 201 is made of Co, CoFeB or Co/Pt, or includes a synthetic antiferromagnetic structure. The bottom electrode 10 is made of one or more of Pt, Ta, or W. The non-magnetic barrier layer 202 may be made of MgO or Al₂O₃. The ferromagnetic free layer 203 is made of Co, CoFe, or CoFeB. The orbital Hall effect layer 40 may be made of Cu or Cr. It is worth noting that the selection of these materials is only for illustrative purposes, and in practical application processes, they may also be replaced by other materials.

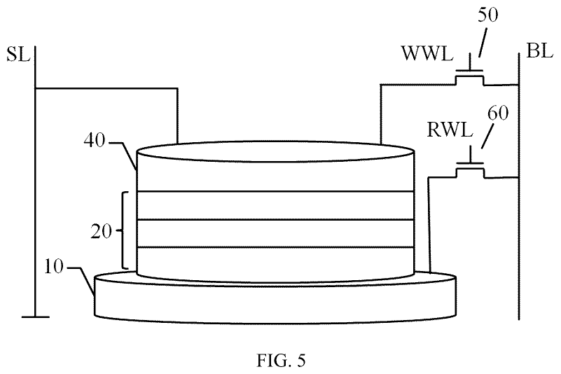

FIG. 5 schematically shows a diagram of a structure of an SOT-MRAM memory cell according to another embodiment of the present disclosure.

As shown in FIG. 5, a difference between a structure of the SOT-MRAM memory cell shown in FIG. 5 and a structure of the SOT-MRAM memory cell shown in FIG. 2 lies in that: the structure of the SOT-MRAM memory cell shown in FIG. 5 does not include a heavy metal layer 30. Other material layers shown in FIG. 5 are consistent with material layers shown in FIG. 2.

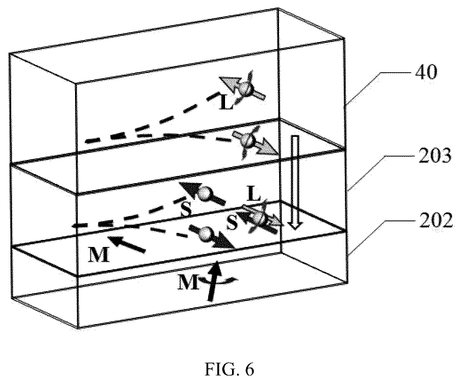

In this embodiment, as shown in FIG. 6, the orbital Hall effect layer 40 and the ferromagnetic free layer 203 (i.e. the ferromagnetic spin-orbit coupling layer) are used to conduct a write current. The orbital Hall effect layer 40 is used to convert the write current into an orbital current with orbital magnetic torque (L) polarization through the orbital Hall effect, and such orbital current may diffuse into the ferromagnetic free layer 203. The ferromagnetic free layer 203 is used to convert the write current into a spin current with spin (S) polarization through the spin-orbit precession effect or the planar Hall effect, while the orbital current that diffuses into the ferromagnetic free layer 203 is converted into a spin current through spin-orbit coupling, and a spin polarization direction of the spin current is determined by a polarity of the spin-orbit coupling of the ferromagnetic layer.

As shown in FIG. 6, at an interface between the orbital Hall effect layer 40 and the ferromagnetic free layer 203, a polarization direction of the intrinsic spin current and a polarization direction of the spin current converted from the orbital current are opposite, so that the intrinsic spin current and the spin current converted from the orbital current form a competition spin current, thereby achieving deterministic magnetization reversal without external magnetic field assistance.

In an embodiment of the present disclosure, the coupling polarities in the orbital Hall effect and the spin Hall effect in a systems of the orbital Hall effect layer, the heavy metal layer and the ferromagnetic layer are described in combination with Table 1.

TABLE 1
Coupling polarities in the orbital Hall
effect and the spin Hall effect

| | Ferromagnetic layer | Ferromagnetic layer |
|---|---|---|
| Coupling polarity | spin-orbit coupling >0 | spin-orbit coupling <0 |
| Non-magnetic layer | Same sign (+) | Opposite sign (−) |
| spin-orbit coupling >0 | | |
| Non-magnetic layer | Opposite sign (−) | Same sign (+) |
| spin-orbit coupling <0 | | |

From Table 1 above, it may be seen that polarities of the spin current converted through the orbital Hall effect and the spin current generated through the spin Hall effect are determined by the polarity of the ferromagnetic layer spin-orbit coupling and the polarity of the heavy metal layer spin-orbit coupling. By configuring the heavy metal layer and the ferromagnetic layer material, the enhancement or competition of the orbital Hall effect to the spin Hall effect may be achieved.

It is worth noting that a layer thickness of each material layer of the memory cell provided in the embodiments of the present disclosure is set according to actual application requirements, as long as it is able to be implemented in the preparation process. The embodiment of the present disclosure does not limit the layer thickness of each material layer.

According to another aspect of the present disclosure, an SOT-MRAM memory is further provided, including the SOT-MRAM memory cell shown in the above embodiments.

In the embodiments, reading and writing operations of data in the memory may be respectively performed by controlling bias voltages on transistors of the SOT-MRAM memory. The control process may also be implemented by using a logic control unit. Specifically, the setting of word lines, bit lines, as well as applied gate voltage bias may be implemented by using the logic control unit, thereby achieving reading and writing of the data, respectively, which will not be limited by embodiments of the present disclosure.

In another embodiment of the present disclosure, an operation method of the SOT-MRAM memory is provided, including: controlling a voltage bias applied to a first transistor and a voltage bias applied to a second transistor in the SOT-MRAM memory, and performing a data writing operation and a data reading operation on the SOT-MRAM memory, respectively. The operation method includes an operation method for data reading and an operation method for data writing, where there is no fixed order to perform the operation method for data reading and the operation method for data writing.

Specifically, as shown in FIG. 2 or FIG. 5, performing the data reading operation on the SOT-MRAM memory includes: controlling the first transistor 50 to be turned off and the second transistor 60 to be turned on, forming a current path of bit line BL-magnetic tunnel junction (MTJ)-source line SL-ground, so as to read data stored in the SOT-MRAM memory through a tunnel magnetoresistance effect.

Specifically, as shown in FIG. 2 or FIG. 5, performing the data writing operation on the SOT-MRAM memory includes: controlling the first transistor 50 to be turned on and the second transistor 60 to be turned off, forming a current path of bit line BL-orbital Hall effect layer/heavy metal layer, so as to form a competition spin current through an orbital Hall effect and a spin Hall effect to achieve data writing to the SOT-MRAM memory.

In yet another embodiment of the present disclosure, a memory array including a plurality of SOT-MRAM memory cells mentioned above is provided. The plurality of SOT-MRAM memory cells are arranged periodically.

Specifically, periodic arranged SOT-MRAM memory cells may share word lines, bit lines, source lines, etc. to achieve a high integration of the device.

In yet another embodiment of the present disclosure, another SOT-MRAM memory is further provided, including the SOT-MRAM memory array mentioned above.

Specifically, the selection of word lines and bit lines in the memory, as well as the setting of applied voltage bias, may be implemented by using the logic control unit, thereby achieving data reading and writing operations, respectively.

From the above description, it may be seen that the embodiments of the present disclosure may achieve at least the following technical effects.

(1) The SOT-MRAM memory cell provided by the present disclosure may achieve data writing without external magnetic field assistance, which is conducive to the large-scale integration of the SOT-MRAM.

(2) The SOT-MRAM memory cell may reduce the use of expensive heavy metal materials, thereby lowering the production cost of the SOT-MRAM.

(3) The SOT-MRAM provided by the present disclosure adopts the competition spin current to achieve a field-free-assisted writing method, rather than introducing structural asymmetry, antiferromagnetic materials, etc., which may improve compatibility with CMOS processes and be conducive to the large-scale preparation and practicality of the SOT-MRAM.

Although the present disclosure has been illustrated and described in detail in the accompanying drawings and previous descriptions, such illustrations and descriptions should be considered illustrative or exemplary rather than restrictive.

Those skilled in the art may understand that the features recited in the various embodiments and/or claims of the present disclosure may be combined in multiple scopes, even if such combinations are not explicitly recited in the present disclosure. Specifically, without departing from the spirit and teachings of the present disclosure, the features recited in the various embodiments and/or claims of the present disclosure may be combined in multiple ways. All these combinations fall within the scope of the present disclosure.

Although the present disclosure has been illustrated and described with reference to specific exemplary embodiments of the present disclosure, those skilled in the art should understand that various changes in form and details may be made to the present disclosure without departing from the spirit and scope of the present disclosure defined by the appended claims and their equivalents. Therefore, the scope of the present disclosure should not be limited to the aforementioned embodiments, but should be determined not only by the appended claims, but also by their equivalents.

1. An SOT-MRAM memory cell, comprising:
a bottom electrode;
a magnetic tunnel junction layer located on the bottom electrode;
an orbital Hall effect layer located on the magnetic tunnel junction layer;
a first transistor, wherein a drain of the first transistor is connected to the orbital Hall effect layer; and
a second transistor, wherein a drain of the second transistor is connected to the bottom electrode.

2. The SOT-MRAM memory cell according to claim 1, further comprising:
a heavy metal layer located between the magnetic tunnel junction layer and the orbital Hall effect layer.

3. The SOT-MRAM memory cell according to claim 2, wherein the orbital Hall effect layer and the heavy metal layer are configured to conduct a write current;
wherein the orbital Hall effect layer is configured to convert the write current into an orbital-polarized orbital current through an orbital Hall effect;
the heavy metal layer is configured to convert the write current into a spin-polarized spin current through a spin-orbit coupling.

4. The SOT-MRAM memory cell according to claim 3, wherein the orbital current that diffuses into the heavy metal layer is converted into a spin current under a strong spin-orbit coupling effect of the heavy metal layer.

5. The SOT-MRAM memory cell according to claim 4, wherein the spin current generated by the heavy metal layer has an opposite polarity to a polarity of the spin current converted from the orbital current, so as to form a competition spin current, wherein the competition spin current is configured to achieve a deterministic magnetization reversal without external magnetic field assistance.

6. The SOT-MRAM memory cell according to claim 1, wherein the magnetic tunnel junction layer comprises: a ferromagnetic reference layer, a non-magnetic barrier layer and a ferromagnetic free layer from bottom to top.

7. The SOT-MRAM memory cell according to claim 6, wherein the ferromagnetic reference layer adopts a pinned structure, comprising: an antiferromagnetic structure layer, a second spatial layer and a reference layer from bottom to top.

8. The SOT-MRAM memory cell according to claim 7, wherein the antiferromagnetic structure layer has an RKKY effect, comprising: a second ferromagnetic layer, a first spatial layer and a first ferromagnetic layer from bottom to top, and the first spatial layer is configured to form an antiferromagnetic coupling between the first ferromagnetic layer and the second ferromagnetic layer.

9. The SOT-MRAM memory cell according to claim 8, wherein a structure composed of the first ferromagnetic layer and the second ferromagnetic layer is a synthetic ferromagnetic structure comprising periodically arranged Co/Pt or Co/Pd.

10. The SOT-MRAM memory cell according to claim 1, further comprising:
a source line and a bit line,
wherein the source line is connected to the orbital Hall effect layer; and
wherein the bit line is connected to a source of the first transistor and a source of the second transistor, respectively.

11. The SOT-MRAM memory cell according to claim 2, wherein the heavy metal layer is of one or more of Pt, Ta, W, or Gd.

12. The SOT-MRAM memory cell according to claim 6, wherein the ferromagnetic reference layer is made of Co, CoFeB or Co/Pt, or comprises a synthetic antiferromagnetic structure;
the bottom electrode is made of one or more of Pt, Ta, or W;
the non-magnetic barrier layer is made of MgO or Al₂O₃;
the ferromagnetic free layer is made of Co, CoFe, or CoFeB;
the orbital Hall effect layer is made of Cu or Cr.

13. An SOT-MRAM memory, comprising the SOT-MRAM memory cell according to claim 1.

14. An operation method of the SOT-MRAM memory according to claim 13, comprising:
controlling a voltage bias applied to a first transistor and a voltage bias applied to a second transistor in the SOT-MRAM memory, and performing a data writing operation and a data reading operation on the SOT-MRAM memory, respectively.

15. The operation method according to claim 14, wherein the performing a data reading operation on the SOT-MRAM memory comprises:
controlling the first transistor to be turned off and the second transistor to be turned on, so as to read data stored in the SOT-MRAM memory through a tunnel magnetoresistance effect.

16. The operation method according to claim 14, wherein the performing a data writing operation on the SOT-MRAM memory comprises:
controlling the first transistor to be turned on and the second transistor to be turned off, so as to form a competition spin current through an orbital Hall effect and a spin Hall effect to write data into the SOT-MRAM memory.

17. An SOT-MRAM memory array, comprising:
a plurality of SOT-MRAM memory cells according to claim 1, wherein the plurality of SOT-MRAM memory cells are arranged periodically.

18. An SOT-MRAM memory, comprising the SOT-MRAM memory array according to claim 17.
